(19) United States
(12) Patent Application Publication
(10) Pub. No.: US 2008/0001141 A1
(43) Pub. Date: Jan. 3, 2008

(54) Doped Transparent and Conducting Nanostructure Networks

(75) Inventors: George Gruner, Los Angeles, CA (US); David Hecht, Santa Monica, CA (US)

Correspondence Address: UNIDYM, 201 SOUTH LAKE AVE., SUITE 703, PASADENA, CA, 91101, US

(73) Assignee: UNIDYM, INC., Pasadena, CA (US)

(21) Appl. No.: 11/563,642

(22) Filed: Nov. 27, 2006

Related U.S. Application Data
(60) Provisional application No. 60/816,875, filed on Jun. 28, 2006.

(51) Int. Cl. H01L 29/08

(52) U.S. Cl. 257/40

(57) ABSTRACT

A doped nanostructure network, devices incorporating a doped nanostructure network and fabrication methods thereof are described. Dopant may be deposited by a solution-based method, and the dopant is preferably stable over an extended period of time. Networks according to embodiments of the present invention can exhibit conductivities in excess of 4000 S/cm.

This application claims priority to U.S. Provisional Patent Application No. 60/816,875, filed Jun. 28, 2006, and entitled “Doped Transparent and Conducting Nanostructure Networks,” which is hereby incorporated herein by reference.

### FIELD OF THE INVENTION

The present invention relates generally to doping silicon materials, and more specifically to doped transparent and conducting nanostructure networks.

### BACKGROUND OF THE INVENTION

Many modern and/or emerging applications require at least one device electrode that has not only high electrical conductivity, but high optical transparency as well. Such applications include, but are not limited to, touch screens (e.g., analog, resistive, improved analog, X/Y matrix, capacitive), flexible displays (e.g., electro-phoretics, electro-luminescence, electrochromatic), rigid displays (e.g., liquid crystal (LCD), plasma (PDP), organic light emitting diode (LED)), solar cells (e.g., silicon (amorphous, protocrystalline, nanocrystalline), cadmium telluride (CdTe), copper indium gallium selenide (CIGS), copper indium selenide (CIS), gallium arsenide (GaAs), light absorbing dyes, quantum dots, organic semiconductors (e.g., polymers, small-molecule compounds)), fiber-optic communications (e.g., electro-optic and opto-electric modulators) and microfluidics (e.g. electrowetting on dielectric (EWOD)). As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some but less than 50% transmission of ambient electromagnetic radiation in relevant wavelengths are said to be “semi-transparent.”

Currently, the most common transparent electrodes are transparent conducting oxides (TCOs), specifically indium-tin-oxide (ITO) on glass. However, ITO can be an inadequate solution for many of the above-mentioned applications (e.g., due to its relatively brittle nature and correspondingly inferior flexibility and abrasion resistance), and the indium component of ITO is rapidly becoming a scarce commodity. Additionally, ITO deposition usually requires expensive, high-temperature sputtering, which can be incompatible with many device process flows. Hence, more robust and abundant transparent conductor materials are being explored.

Nanostructure-films, such as those comprising networks of nanotubes, nanowires, nanoparticles and/or graphene flakes, have attracted a great deal of recent attention due to their exceptional material properties. Specifically, films comprising carbon nanotubes network(s) can exhibit extraordinary strength and unique electrical properties, as well as efficient heat conduction. However, nanotube networks fabricated to date, while both conducting and transparent, have not been able to achieve the levels of sheet conductance and transparency necessary to compete with currently used materials such as ITO.

Doping is a promising strategy for lowering the sheet resistance of nanostructure networks. Doping has been performed before on individual carbon nanotube transistors, where metal-nanotube interfaces (the so-called Schottky barrier) dictate conductance. (T. Takenobu et al, Adv. Mat. 17, 2430 (2005); J. Chen et al, Apply. Phys. Lett. 86 123108 (2005); A. Afzani-Ardakani et al, U.S. Patent Application 20060038179). Not surprisingly, data from such devices does not provide much information regarding the effect of doping a nanostructure network, e.g., on the change in optical and electrical properties.

Carbon nanotube networks have been doped using inorganic species such as K, Br₂, SOCl₂ and NO₂. (Kong et al, Science 287 (2000); Lee et al, Nature 388 (1997); S. Ruzicka et al, Phys. Rev. 61, 2468 (2000); U. Dettlaff-Wegilowska et al, J. Am. Chem. Soc. 127, 5125 (2005)), however such species are typically very unstable, and are consequently removed from the nanotubes with time. For example, doping with NO₂ results in an increased conductivity, but dopant (NO₂) inevitably evaporates from the nanotube film, due to the small binding energy between NO₂ and the nanotubes. In addition, only modest increase of the network conductivity has been observed. Finally, the literature has not described techniques for doping transparent networks or explored the effects of doping on the transparency of the networks.

### SUMMARY

The present invention describes doped nanostructure networks and structures based on such networks, which preferably have unique properties such as high conductivity, low sheet resistance, high transparency, and stability over extended periods of time. The nanostructures can be, but are not limited to, single-walled carbon nanotubes, multi-walled carbon nanotubes, double-walled carbon nanotubes, few-walled carbon nanotubes, fullerenes, graphene flakes/sheets, or semiconductor nanowires such as silicon nanowires. Preferably, the nanostructures are single-walled carbon nanotubes (SWNTs).

One embodiment of the invention is a nanostructure network doped with organic species that can have a conductivity of 4000 S/cm and a transparency of at least 70%. Another embodiment of the invention is a structure comprising more than one layer, wherein at least one layer comprises a network of nanostructures and at least one layer comprises dopant molecules. The multi-layered structure has a transparency of at least 50% and a sheet resistance of less than 180 Ohms/sq. In another embodiment of the invention, a composite comprising a network of nanostructures intercalated with organic dopant molecules is described. Another embodiment of the invention is a structure comprising a nanostructure network, dopant molecules, and an encapsulation layer. The structure is preferably stable over an extended period of time. Methods of making these compositions and structures according to embodiments of the present invention are also provided.

Other features and advantages of the invention will be apparent from the accompanying drawings and from the detailed description. One or more of the above-disclosed embodiments, in addition to certain alternatives, are provided in further detail below with reference to the attached figures. The invention is not limited to any particular embodiment disclosed.

### BRIEF DESCRIPTION OF THE DRAWINGS

The invention is better understood from reading the following detailed description of the preferred embodiments, with reference to the accompanying figures in which:

FIG. 1 is a graph of the sheet resistance of carbon nanotube films as a function of the drops of doping solution (e.g., a saturated solution of TCNQF₄ in carbon disulfide (CS₂) solution) applied to the films. The films had an optical transparency of 74.7% (using “P3” nanotubes from Carbon Solutions Inc.), and this transparency was unchanged by doping. The carbon nanotube films were initially sprayed on glass, and drops of the doping solution were added to the film on glass and allowed to dry.

FIG. 2 is a schematic representation of device architectures according to embodiments of the present invention. A nanotube network printed on PET (FIG. 2a) exhibited 61% transparency at 180 Ohms/sq, with a corresponding dc conductivity of 745 S/cm), while two nanotube networks printed on PET with a layer of TCNQF₄ between them (FIG. 2b) exhibited 57% transparency at 100 Ohms/sq, with a corresponding dc conductivity of 1200 S/cm.

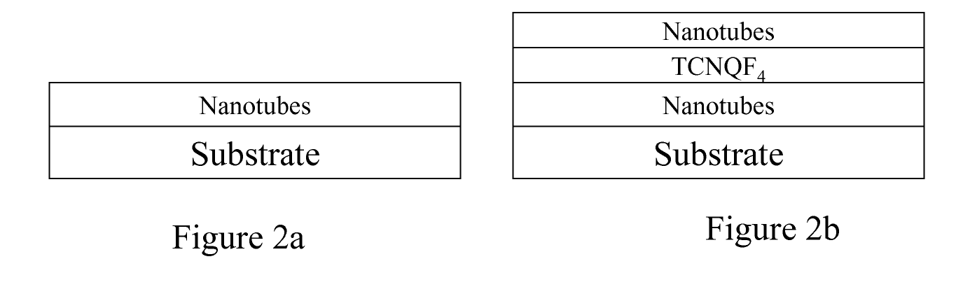

FIG. 3 is a schematic representation of a multilayer structure according to a further embodiment of the present invention, comprising alternating layers of nanotube networks and dopant (TCNQF₄ in this example) on a substrate.

FIG. 4 is a schematic representation of a multilayer structure according to additional embodiments of the present invention, comprising an encapsulation layer and a doped nanotube layer deposited on a substrate. The encapsulation and doped nanotube layers may be deposited on the same side (FIG. 4a) or on different sides (FIG. 4b) of the substrate without departing from the scope of the present invention.

FIG. 5 is a graph of the resistance of a nanotube network versus time upon exposure to an NO₂ doping gas.

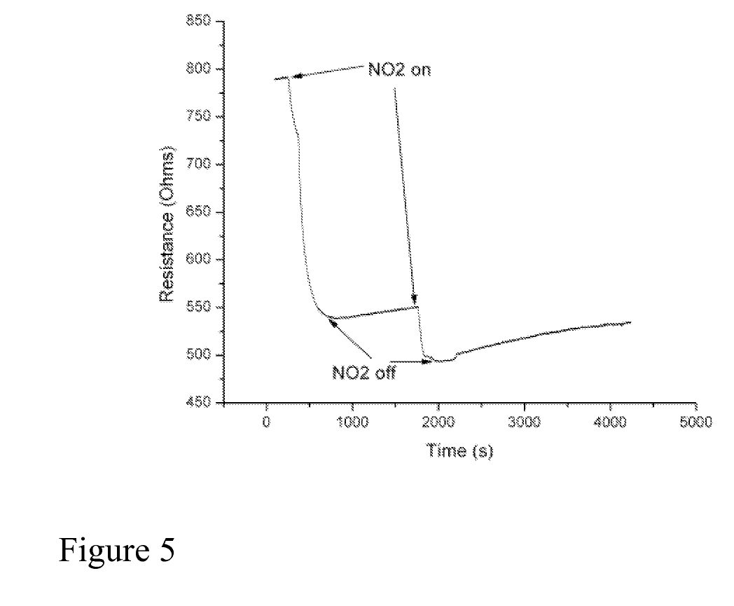

### DETAILED DESCRIPTION OF THE EMBODIMENTS

### First Embodiment

A first embodiment of the invention comprises a nanostructure network doped with an organic species. Such dopants can lead to a network conductivity of more than 4000 S/cm. Preferably, the doped nanostructure network has a transparency of at least 70%, and the nanostructures are single-walled carbon nanotubes.

First, nanostructures are solubilized in a solution. Preferably, the solution is aqueous. Additionally or alternatively, the nanostructures can be dissolved in solvents such as dichlorobenzene, chloroform, or dimethylformamide. The solution may include a suitable surfactant such as sodium dodecyl as a solubilization agent. The solvent can also include other solubilization agents such as DNA or polymers. In a preferred embodiment, the solution is then sonicated for a period of time.

After being solubilized, the solution is purified to remove impurities. An example of a suitable purification method is centrifugation, which results in separation of the liquid containing soluble compounds and concentrated material at the bottom of the centrifuge. The solution is then deposited on a substrate. Deposition methods include, but are not limited to, spraying, drop casting, spin coating, vacuum filtration, dip coating, and printing. Preferably, spraying and/or printing are used.

The dopant molecule is then dissolved in an appropriate solution. Suitable dopant molecules include, but are not limited to, tetrafluorocyano-p-quinodimethane (TCNQF₄), tetracyano-p-quinodimethane (TCNQ), tetrafluorocyano-p-quinodimethane (TCNQF₄), tetrathiafulvalene (TTF), tetrakis(dimethylamino)ethylene (TDAE), tetramethyl-tetraselenafulvalene (TMTSF), pentacene (C₂₂H₁₄), tetracene (C₁₈H₁₂), anthracene (C₁₄H₁₀), fullerene (C₆₀), and triehyloxonium hexachloroantimonate. Preferably, tetrafluorocyano-p-quinodimethane (TCNQF₄) is used as the doping molecule. Examples of suitable solvents include, but are not limited to, water, water with surfactant, dimethylformamide, dichlorobenzene, and carbon disulfide (CS₂). Preferably, carbon disulfide is used as the solvent. Enough of the dopant molecule should be added to form a saturated solution.

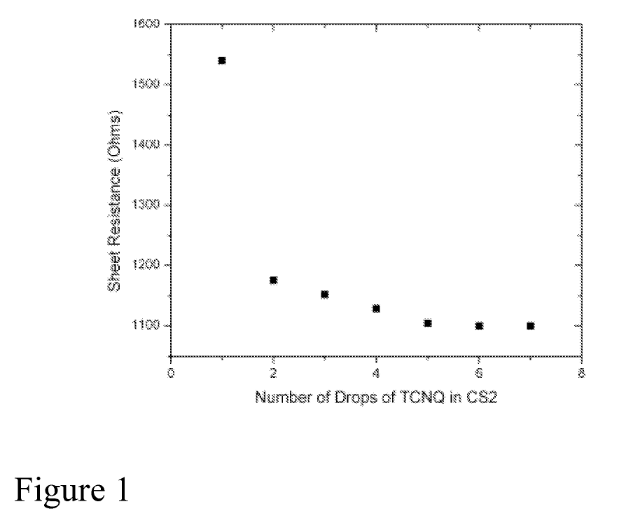

The solution containing the dissolved dopant is then added to the nanostructure network by either dropping the solution on top of the film and allowing it to dry, soaking the nanostructure network in solution, and/or spraying down a layer of solution on top of nanostructure network. FIG. 1 shows the change in sheet resistance of a nanostructure network sprayed on a glass substrate upon the addition of drop(s) of a solution of a dopant molecule in a solvent. A doped nanostructure network can obtain a conductivity of 4000 S/cm. The optical transparency of the nanostructure networks do not change based on addition of dopant molecules.

Example

P3 nanotubes from Carbon Solutions were solubilized in a solution of water, by sonication. Sodium dodecyl sulfate was used as surfactant. The solution was centrifuged to remove impurities. The solution was applied to a glass substrate by spraying. Tetrafluorocyano-p-quinodimethane (TCNQF₄) was dissolved in Carbon Disulfide (CS₂) to form a saturated solution. The solution of CS₂ with dissolved TCNQF₄ was added to the sprayed carbon nanotube film by dropping the solution on top of the film. FIG. 1 shows the change in resistance of a nanotube film sprayed on a glass substrate upon addition of drops of a solution of a dopant molecule in a solvent. The sheet resistance of the nanotube networks decreased dramatically based upon addition of the dopant molecules. A doped nanostructure network can obtain a conductivity of 4000 S/cm. The nanotube networks had an optical transparency of 74.7% that did not change based on addition of dopant molecules.

### Second Embodiment

Another embodiment of the invention is a structure comprised of more than one layer, where at least one layer is a network of nanostructures and at least one layer is comprised of dopant molecules. Preferably, the nanostructures are single-walled carbon nanotubes, and the dopant molecules are TCNQF₄. The structure has a transparency of at least 50% and a sheet resistance of less than 180 Ohms/sq.

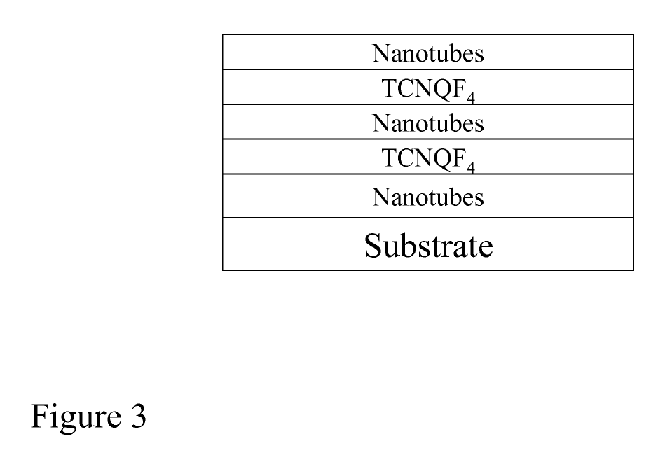

Nanostructures are prepared in solution, and the dopant molecules are prepared in solution according to the techniques previously described. Several methods may be used to form the multi-layered structure. Preferably, a vacuum filtration process is used. The solution is vacuum filtered through a porous membrane, with the nanostructure network being deposited on top of the filter. The network can be washed while on the filter with any of numerous liquids to remove surfactant, functionalization agents, or unwanted particles. A solution of dopants is then vacuum filtered over the nanostructures, such that the dopant molecules form a layer coating the nanostructures. Then, the solution of nanostructures is again filtered through the filter. This forms a sandwich structure, where a layer of nanostructures alternates with a layer of dopant molecules. This process may be repeated several times to form a structure with alternating layers of nanostructures and dopant molecules, as in FIG. 3. The film may then be printed from the filter using a PDMS stamp.

An alternative method of making the structure is to spray a layer of nanostructures, then soak that layer in a solution containing the dopant molecule, then to spray another layer of nanostructures, and repeat the process to get the desired transparency/resistance.

Example

P3 nanotubes from Carbon Solutions were solubilized in a solution of water, by sonication. The solution included sodium dodecyl sulfate. The solution was then sonicated and centrifuged to remove impurities. The nanotubes were applied to a filter by vacuum filtration, and the surfactant was washed by water. A solution of TCNQF₄ in CS₂ was then vacuum filtered over the nanotubes, such that the dopant molecules formed a layer coating over the tubes. Then, the solution of carbon nanotubes was again filtered through the filter. This formed a sandwich structure, where a layer of carbon nanotubes alternated with a layer of dopant molecule. This process was repeated several times to form a structure with alternating layers of nanotubes and dopant molecules, as shown in FIG. 3. The film was then printed from the filter using a PDMS stamp. The resulting structure had a transparency of 57%, a sheet resistance of 100 Ohms/sq conductivity, and a conductivity of 1200 S/cm.

### Third Embodiment

Another embodiment of the invention is a composite structure comprised of a network of nanostructures intercalated with organic dopant molecules. Preferably, the nanostructures are single-walled carbon nanotubes, and the dopant molecules are TCNQF₄. A suitable solvent is used that can simultaneously solubilize both the nanotubes and the dopant molecules. For example, TCNQF₄ can be solubilized by SDS surfactant, so that one can make a solution containing water, SDS, nanotubes, and TCNQF₄ all mixed together. This solution can then be sprayed to a substrate, or deposited to a filter. This would form a structure consisting of an intermixed nanostructure/dopant molecule layer.

### Fourth Embodiment

Another embodiment of the invention is a structure comprising a nanostructure network, dopant molecules, and an encapsulation layer. Preferably, the nanostructure network is comprised of single-walled carbon nanotubes, and the dopant molecules are TCNQF₄. The encapsulation layer can be comprised of, for example, parylene, polydimethylsiloxane (PDMS), and polyimide. By containing the doping species, the encapsulation layer enables a doped structure that is stable over an extended period of time.

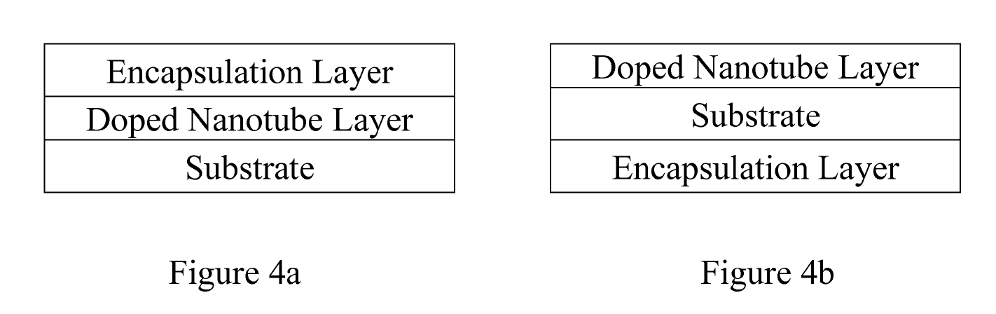

A structure comprised of multiple layers of nanostructure networks and dopant molecules or a composite comprised of a nanostructure network and dopant molecules can be formed according to the techniques previously described. An encapsulation layer can be deposited on top of the nanotube film in order to encapsulate the doping species, as shown in FIG. 4a. The encapsulation layer can be evaporated on top, or spin coated over the top of the nanotube film, and may or may not be followed by a baking step.

An alternate structure can be for the encapsulation layer to cover the back side of the substrate, to prevent evaporation of the dopant molecule through the substrate. This is shown in FIG. 4b.

The present invention has been described above with reference to preferred features and embodiments. Those skilled in the art will recognize, however, that changes and modifications may be made in these preferred embodiments without departing from the scope of the present invention. These and various other adaptations and combinations of the embodiments disclosed are within the scope of the invention.

1. A composition of matter, comprising:
a network of nanostructures; and
a dopant, wherein the network of nanostructures is doped by the dopant, and
wherein the composition of matter has a conductivity of at least 4000 S/cm and a transparency of at least 70%.

2. The composition of matter of claim 1, wherein the dopant is an organic species.

3. The composition of matter of claim 2, wherein the nanostructures are carbon nanotubes.

4. The composition of matter of claim 3, wherein the network of nanostructures is intercalated with the dopant.

5. The composition of matter of claim 4, wherein doping is stable over an extended period of time.

6. A multilayer structure, comprising:
at least one layer comprising a network of nanostructures; and
at least one layer of dopant molecules, wherein like layers are deposited on non-like layers, and
wherein the multilayer structure has a conductivity of at least 4000 S/cm and a transparency of at least 70%.

7. The multilayer structure of claim 6, wherein doping is stable over an extended period of time.

8. The multilayer structure of claim 7, wherein the nanostructures are carbon nanotubes.

9. The structure of claim 8, further comprising an encapsulation layer forming an outer layer of the multilayer structure.

10. The structure of claim 9, wherein the dopant molecules comprise tetrafluorocyano-p-quinodimethane.

11. A method of fabricating a doped nanostructure device, comprising depositing a layer of dopant on a network of nanostructures, wherein the doped nanostructure device has a conductivity of at least 4000 S/cm and a transparency of at least 70%.

12. The method of claim 11, wherein the dopant is deposited using a solution-based method.

13. The method of claim 12, wherein the dopant is deposited by at least one of spraying, drop casting, spin coating, vacuum filtration, dip coating, and printing.

14. The method of claim 13, wherein the dopant does not affect transparency of the network of nanostructures.

15. The method of claim 14, further comprising depositing a network of nanostructures on a surface by at least one of spraying, drop casting, spin coating, vacuum filtration, dip coating, and printing.

16. The method of claim 15, wherein the nanostructures are carbon nanotubes.

17. The method of claim 16, further comprising:
depositing at least one additional layer of nanostructures; and
depositing at least one additional layer of dopant, wherein like layers are deposited on non-like layers.

18. The method of claim 17, wherein the dopant comprises tetrafluorocyano-p-quinodimethane.

19. The method of claim 18, further comprising depositing an encapsulation layer, wherein the encapsulation layer forms an outer layer on the doped nanostructure device.

20. The method of claim 19, wherein the doped nanostructure device is at least one of an optoelectronic device, a touch screen, a microfluidic device, an electromagnetic shield, a sensor and a display.
